(19) United States
(12) Patent Application Publication
(10) Pub. No.: US 2017/0222143 A1
(43) Pub. Date: Aug. 3, 2017

(54) Resistive Random Access Memory

(71) Applicant: NATIONAL SUN YAT-SEN UNIVERSITY, Kaohsiung City (TW)

(72) Inventors: Ting-Chang Chang, Kaohsiung City (TW); Kuan-Chang Chang, Kaohsiung City (TW); Tsung-Ming Tsai, Kaohsiung City (TW); Tian-Jian Chu, Kaohsiung City (TW); Chih-Hung Pan, Kaohsiung City (TW)

(21) Appl. No.: 15/156,401

(22) Filed: May 17, 2016

(30) Foreign Application Priority Data
Feb. 1, 2016 (TW) 105103135

(51) Int. Cl. H01L 45/00

(52) U.S. Cl. CPC H01L 45/1286; H01L 45/085; H01L 45/1233; H01L 45/1266; H01L 45/146

(57) ABSTRACT

A resistive random access memory is provided to solve the problem of low switching speed of the conventional resistive random access memory. The resistive random access memory may include a thermally conductive layer, a first electrode layer, a heat preserving element, a resistance changing layer and a second electrode layer. The first electrode layer is arranged on the thermally conductive layer. The heat preserving element is arranged on the first electrode layer and forms a through-hole. A part of a surface of the first electrode layer is exposed to the through-hole. The resistance changing layer extends from the part of the surface of the first electrode layer to a surface of the heat preserving element that is located outside the through-hole. The second electrode layer is arranged on the resistance changing layer.

The application claims the benefit of Taiwan application serial No. 105103135, filed on Feb. 1, 2016, and the subject matter of which is incorporated herein by reference.

### BACKGROUND OF THE INVENTION

1. Field of the Invention

The present disclosure generally relates to a resistive random access memory and, more particularly, to a resistive random access memory having a high switching speed.

2. Description of the Related Art

Memories have been widely used in various electronic products. Due to the increasing need of data storage, the demands of the capacities and performances of the memories become higher and higher. Among various memory elements, resistive random access memories (RRAMs) have an extremely low operating voltage, an extremely high read/write speed, and high miniaturization of the element size and, thus, may replace the conventional flash memories and dynamic random access memories (DRAMs) as the main stream of memory elements of the next generation.

A conventional resistive random access memory generally includes a bottom electrode, a dielectric layer, a resistance changing layer and an upper electrode. The dielectric layer is arranged on the bottom electrode. The dielectric layer forms a through-hole. The surface of the bottom electrode is partially exposed to the through-hole. As such, the resistance changing layer extends from the surface of the bottom electrode, which is exposed to the through-hole, to an upper surface of the dielectric layer. The upper electrode is arranged on the resistance changing layer. In the above arrangement, an electric field can be applied to switch the resistance changing layer between a low resistance state (LRS) and a high resistance state (HRS). Such a resistive random access memory can be seen in the academic paper entitled “Characteristics and Mechanisms of Silicon-Oxide-Based Resistance Random Access Memory” as published on IEEE ELECTRON DEVICE LETTERS, VOL. 34, NO. 3 on MARCH 2013.

However, since the reduction in size of the electronic device leads to an increase in the operational speed of the electronic device, the operational speed of the resistance random access memory must be further increased (i.e. increase the switching speed of the resistance state) to meet the future trend in the application of the electronic device.

In light of this, it is necessary to improve the conventional resistive random access memory.

### SUMMARY OF THE INVENTION

It is therefore the objective of this disclosure to provide a resistive random access memory.

In an embodiment of the disclosure, a resistive random access memory may include a thermally conductive layer, a first electrode layer, a heat preserving element, a resistance changing layer and a second electrode layer. The first electrode layer is arranged on the thermally conductive layer. The heat preserving element is arranged on the first electrode layer and forms a through-hole. A part of a surface of the first electrode layer is exposed to the through-hole. The resistance changing layer extends from the part of the surface of the first electrode layer to a surface of the heat preserving element that is located outside the through-hole. The second electrode layer is arranged on the resistance changing layer.

In another embodiment, a resistive random access memory includes a thermally conductive layer, a first electrode layer, a heat preserving element, a resistance changing layer and a second electrode layer. The first electrode layer is arranged on the thermally conductive layer. The heat preserving element is arranged on the thermally conductive layer, surrounds the first electrode layer, and forms a through-hole. The first electrode layer is located in the through-hole. The resistance changing layer extends from the first electrode layer to a surface of the heat preserving element that is located outside the through-hole. The second electrode layer is arranged on the resistance changing layer.

In a form shown, the thermally conductive layer includes a protrusion. The first electrode layer may be arranged on the protrusion. The protrusion and the first electrode layer are located in the through-hole of the heat preserving element. The protrusion includes a periphery that is securely coupled with an inner periphery of the thermally insulating layer forming the through-hole. As such, the switching process of the resistance state can be effectively speeded up and the thermally insulating effect is improved under the electrothermal effect.

In the form shown, the thermally conductive layer may be made of gold, silver, copper, iron, aluminum, or any combination thereof. As such, efficient transfer of the electrothermal energy can be attained to speed up the switching process of the resistance state of the resistance changing layer via the thermal energy.

In the form shown, the heat preserving element is a composition including silicon dioxide or hafnium dioxide. The heat preserving element may include a thermally insulating material. The thermally insulating material may have a thermal conductivity of smaller than 1.26 W/m·° C.

In the form shown, the heat preserving element includes a thermally insulating layer surrounding a part of the resistance changing layer. The thermally insulating layer may be made of reinforced carbon-carbon composite, high temperature reusable surface insulation tiles, fibrous refractory composite insulation tiles, flexible insulation blankets, or toughened unipiece fibrous insulation. As such, the heat dissipation is effectively reduced, and the switching process of the resistance state of the resistance changing layer can be speeded up.

In the resistive random access memories presented above, the resistance changing layer is used to reduce the dissipation of the electrothermal energy, and the first electrode layer and the thermally conductive layer are used to provide an efficient heat transfer over the resistance changing layer in order to increase the amount of oxygen ions that are thermally activated. As such, the formation of the filament and the switching process of the resistance state can be speeded up. Therefore, the resistive random access memories of the disclosure are able to shorten the data access time. Advantageously, the resistive random access memories of the disclosure can be used in an equipment which requires a high data access speed (such as a real-time operating system), or can shorten the calculation time when a large amount of data is processed. As such, the industrial development can be facilitated.

### BRIEF DESCRIPTION OF THE DRAWINGS

The present disclosure will become more fully understood from the detailed description given hereinafter and the accompanying drawings which are given by way of illustration only, and thus are not limitative of the present disclosure, and wherein:

FIG. 1 is a cross sectional view of a resistive random access memory according to a first embodiment of the disclosure.

FIG. 2a shows a characteristic curve of the electrical energy of the resistive random access memory measured at a constant operating voltage.

FIG. 2b shows a characteristic curve of the resistance of the resistive random access memory measured at the constant operating voltage.

FIG. 3a shows an initial state of a thermal activation process of the oxygen ions when an electric field is applied to a resistance changing layer of the resistive random access memory.

FIG. 3b shows a further state of the thermal activation process of the oxygen ions of the resistance changing layer of the resistive random access memory.

FIG. 3c shows a final state of the thermal activation process of the oxygen ions of the resistance changing layer of the resistive random access memory.

FIG. 4a shows a plurality relation curves between a ratio of switching time/raising time and an amount of electrical energy when the resistive random access memory of the first embodiment of the disclosure is measured at different temperatures.

FIG. 4b shows a relation curve between the ratio of switching time/raising time and the temperature according to the resistive random access memory of the first embodiment of the disclosure.

FIG. 5 shows a heat dissipation process of the resistive random access memory of the first embodiment of the disclosure.

FIG. 6 is a cross sectional view of a resistive random access memory according to a second embodiment of the disclosure.

FIG. 7 is a cross sectional view of a resistive random access memory according to a third embodiment of the disclosure.

In the various figures of the drawings, the same numerals designate the same or similar parts. Furthermore, when the terms “first”, “second”, “third”, “fourth”, “inner”, “outer”, “top”, “bottom”, “front”, “rear” and similar terms are used hereinafter, it should be understood that these terms have reference only to the structure shown in the drawings as it would appear to a person viewing the drawings, and are utilized only to facilitate describing the disclosure.

### DETAILED DESCRIPTION OF THE INVENTION

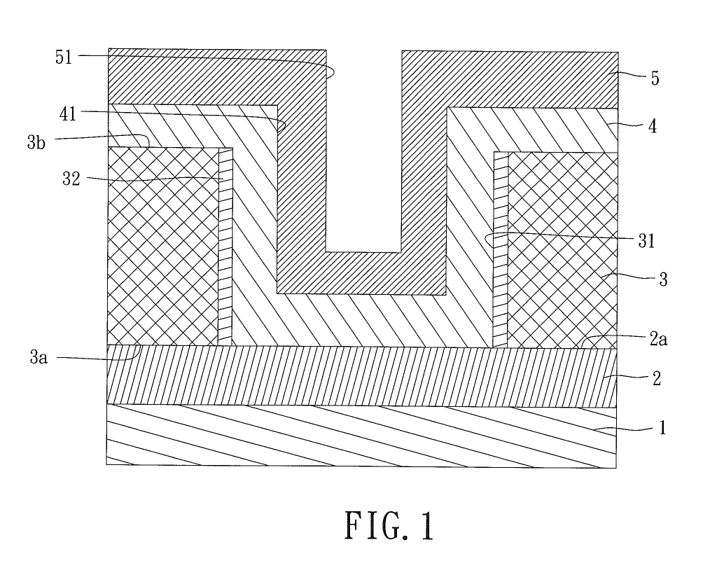

FIG. 1 is a cross sectional view of a resistive random access memory according to a first embodiment of the disclosure. The resistive random access memory according to the first embodiment of the disclosure may include a thermally conductive layer 1, a first electrode layer 2, a heat preserving element 3, a resistance changing layer 4 and a second electrode layer 5. The thermally conductive layer 1, the first electrode layer 2, the heat preserving element 3, the resistance changing layer 4 and the second electrode layer 5 may be stacked with each other to form the resistive random access memory. The first electrode layer 2 is arranged on the thermally conductive layer 1. The heat preserving element 3 forms a through-hole 31 such that the surface of the first electrode layer 2 is partially exposed to the through-hole 31. The resistance changing layer 4 may extend from the surface of the first electrode layer 2, which is exposed to the through-hole 31, to the upper surface of the heat preserving element 3. The second electrode layer 5 is arranged on the resistance changing layer 4. In the embodiment, an external power (not shown) may be applied between the first electrode layer 2 and the second electrode layer 5 to generate an electric field on the resistive random access memory. As such, the resistance state of the resistance changing layer 4 can be changed. The detailed implementation of the first embodiment of the resistive random access memory is described below, but is not limited thereto.

For example, as shown in FIG. 1, the thermally conductive layer 1 may be made of a thermally conductive material with high thermal conductivity in order to rapidly dissipate the heat of the first electrode layer 2 generated during the operation of the resistive random access memory. Such a material may include a metal plate (made of gold, silver, copper, iron, aluminum or any combination thereof), a thermally conductive film, or a thermally conductive adhesive/paste. The first electrode layer 2 may be made of an electrically conductive material, such as titanium oxide or platinum oxide. The first electrode layer 2 may include a mounting face 2a on which the heat preserving element 3 is mounted.

In the example, the heat preserving element 3 is a composition including silicon dioxide (SiO₂) or hafnium dioxide (HfO₂). The heat preserving element 3 may further include a thermally insulating material with excellent thermal insulation property, such as the one with a thermal conductivity of smaller than 1.26 W/m. As a result, the heat preserving element 3 can reduce the speed the heat is dissipated from the heat preserving element 3. Furthermore, a thermally insulating layer 32 may be arranged on an inner periphery of the heat preserving element 3 forming the through-hole 31. The thermally insulating layer 32 may surround a part of the resistance changing layer 4. Furthermore, the thermally insulating layer 32 may be in the form of a film such as reinforced carbon-carbon (RCC) composite, high temperature reusable surface insulation tiles (HRSI), fibrous refractory composite insulation tiles (FRCI), flexible insulation blankets (FIB) or toughened unipiece fibrous insulation (TUFI). Such a film is used to prevent rapid heat dissipation of the through-hole 31. The heat preserving element 3 includes two opposite surfaces 3a and 3b in which the through-hole 31 extends through the heat preserving element 3 from the surface 3a to the surface 3b. The surface 3a may be in contact with the mounting face 2a of the first electrode layer 2. The resistance changing layer 4 may be partially arranged on the surface 3b.

In the example, the resistance changing layer 4 may be formed by a material with changeable resistance, which may be an oxide such as the composition of silicon dioxide (SiO₂) and hafnium dioxide (HfO₂). The resistance changing layer 4 may extend from the surface of the first electrode layer 2, which is exposed to the through-hole 31, to an upper surface of the heat preserving element 3 through the inner periphery of the heat preserving element 3. In addition, the resistance changing layer 4 may form a recess 41 (by etching, for example). The recess 41 may extend into the through-hole 31 such that the electric field can be concentrated on the portion of the resistance changing layer 4 inside the through-hole 31. As such, the heat can be accumulated in the through-hole 31 to shorten the period of transition time that is required for the oxygen ions of the resistance changing layer 4 to switch between the resistance states. Accordingly, a high switching speed of the resistance state can be achieved.

The second electrode layer 5 may be formed by an electrically conductive material such as indium tin oxide or platinum. The second electrode layer 5 may extend from the recess 41 to an upper surface of the resistance changing layer 4, and form a notch 51 having a shape in correspondence to the shape of the recess 41. The notch 51 is located in the recess 41 such that the electric field can be concentrated on the resistance changing layer 4.

Referring to FIG. 1 again, during the use of the resistive random access memory according to the first embodiment of the disclosure, an electric field can be applied to the resistance changing layer 4 via the first electrode layer 2 and the second electrode layer 5. The electric field may act on the oxygen ions (O²⁻) of the resistance changing layer 4 in different ways (such as different positive or negative voltages) to cause a redox reaction of the resistance changing layer 4. For example, a filament may be formed by the reduction effect to reduce the resistance, or may be eliminated by the oxidation effect to increase the resistance. The resistance changing layer 4 may switch between different resistance states through a set process or a reset process. For instance, when the applied positive voltage exceeds a set voltage, the resistance changing layer may switch from the high resistance state (HRS) to the low resistance state (LRS). To the contrary, when the applied negative voltage exceeds a reset voltage, the resistance changing layer may switch from the low resistance state to the high resistance state. The principle on how the oxygen ions of the resistance changing layer 4 are thermally activated to speed up the switching process of the resistance state is explained below.

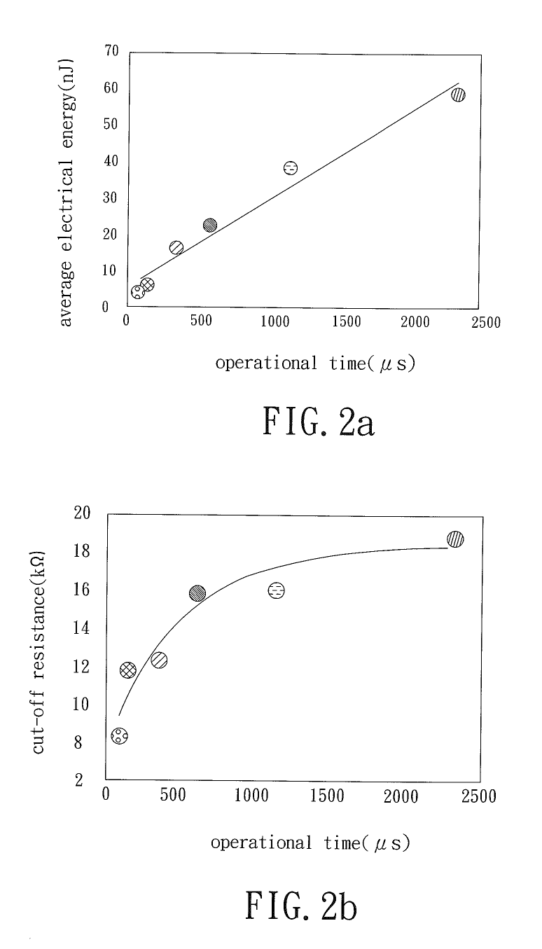

As an example of the reset process (from low resistance state to high resistance state) in the above embodiment, when the resistance changing layer 4 operates under a predetermined voltage, the electrical energy and heat will be accumulated in the resistance changing layer 4 as time passes, as shown in FIGS. 2a and 2b. The heat can quickly spread over the resistance changing layer 4 via the first electrode layer 2 and the thermally conductive layer 1 to gradually activate the oxygen ions of the resistance changing layer 4 in order to shorten the period of time that is required for the resistive random access memory to switch to a stable resistance state (such as high resistance state), as elaborated later.

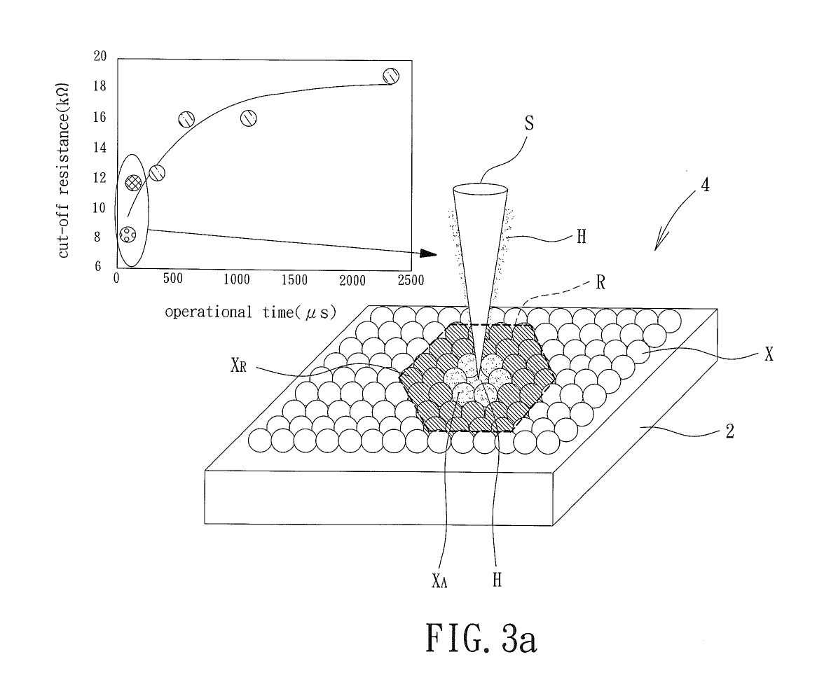

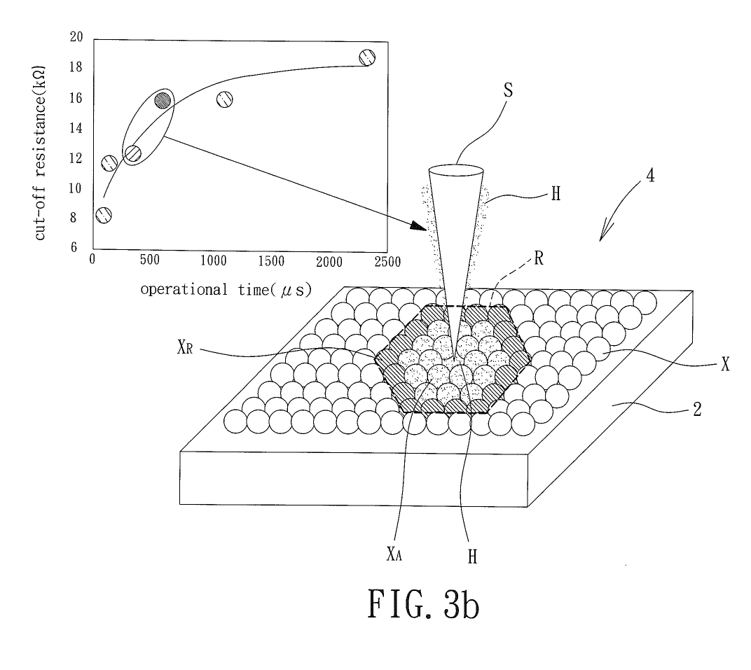

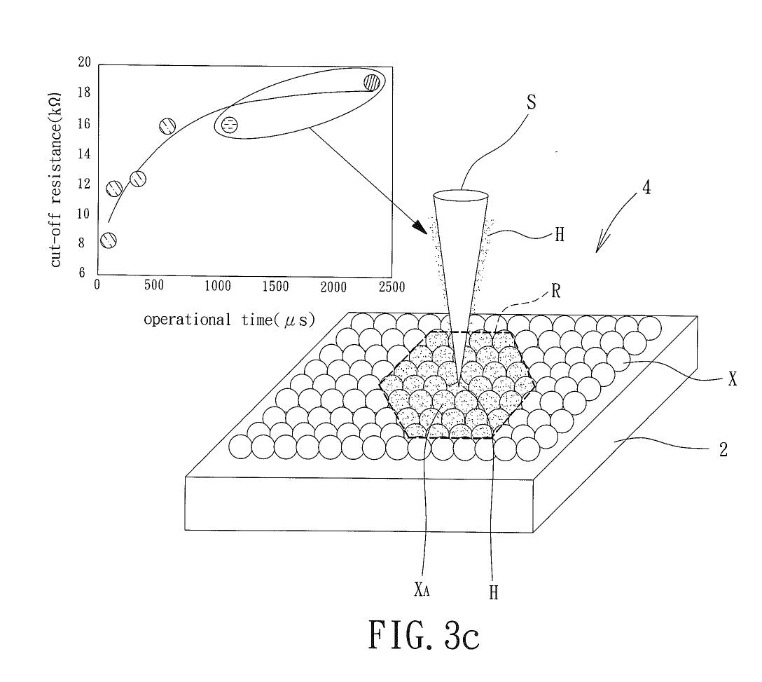

Specifically, the resistance changing layer 4 contains a large number of oxygen ions “X” as shown in FIG. 3a. Initially, the electric field heats a plurality of working oxygen ions “X_{R}” in a working range “R.” In the initial moment (from 100 to 200 μs), the plurality of working oxygen ions “X_{R}” is thermally activated as active oxygen ions “X_{A}.” Since the active oxygen ions “X_{A}” are in a high speed motion state, they are able to apply the heat “H” to the filament “S.” Thus, the switching process of the resistance state of the resistance changing layer 4 can be speeded up (such as the resistance rapidly changing from 8 kΩ to 12 kΩ, for example). Then, as shown in FIG. 3b, the heated oxygen ions “X_{A}” will pass its heat to the adjacent oxygen ions, thereby increasing the amount of the active oxygen ions “X_{A}.” In this regard, more and more active oxygen ions “X_{A}” participate in the switching process of the resistance state (such as the resistance changing from 12 kΩ to 16 kΩ, for example). Finally, as shown in FIG. 3c, almost all of the working oxygen ions “X_{R}” in the working range “R” become active oxygen ions “X_{A}.” In this stage, there are the most active oxygen ions “X_{A}” that participate in the switching process of the resistance state, thus stably switching the resistance changing layer 4 to the desired state (such as the resistance of 18k0, for example).

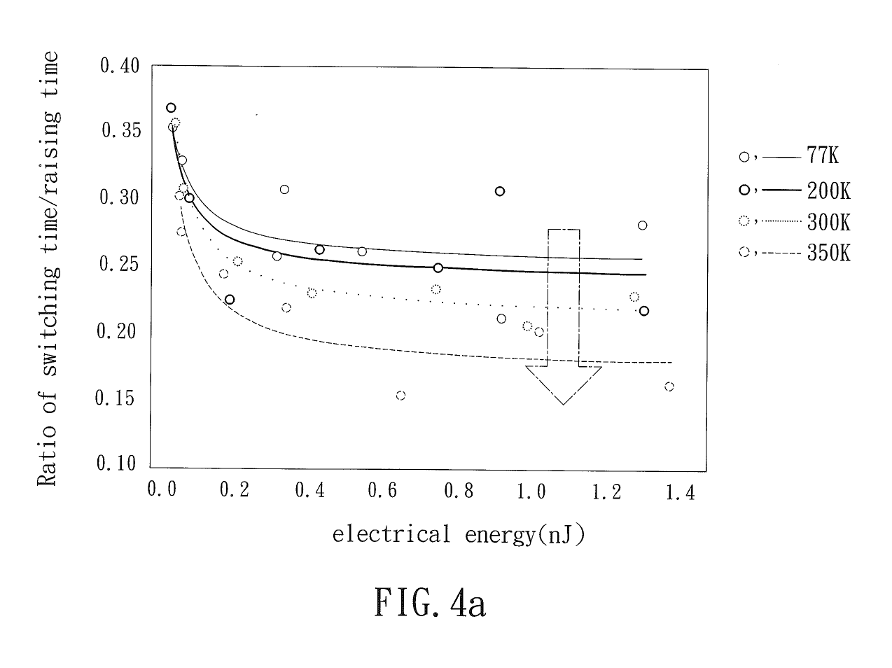

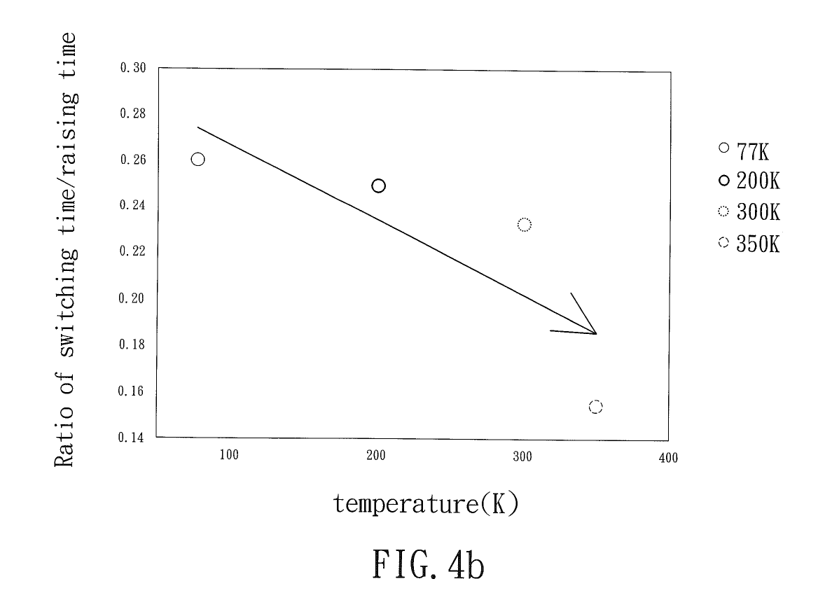

FIG. 4a shows a plurality relation curves between a ratio of switching time/raising time and an amount of electrical energy when the resistive random access memory of the first embodiment of the disclosure is measured at different temperatures. The plurality of relation curves may be obtained from the experiments conducted in different temperatures. The plurality of relation curves is used to represent the ratio of switching time/raising time at the temperature of 77K, 220K, 300K and 350K. From FIG. 4a, it can be observed that the ratio of switching time/raising time decreases as the amount of electrical energy increases. As such, the switching process of the resistance state (such as reset) can be faster. FIG. 4b shows a relation curve between the ratio of switching time/raising time and the temperature according to the resistive random access memory of the first embodiment of the disclosure. It can be known from FIGS. 4a and 4b that the ratio of switching time/raising time tends to decrease as the temperature increases (such as 77K->200K->300K->350K). The larger the amount of the accumulated energy the faster the filament is heated, leading to a high switching speed of the resistance state (such as reset).

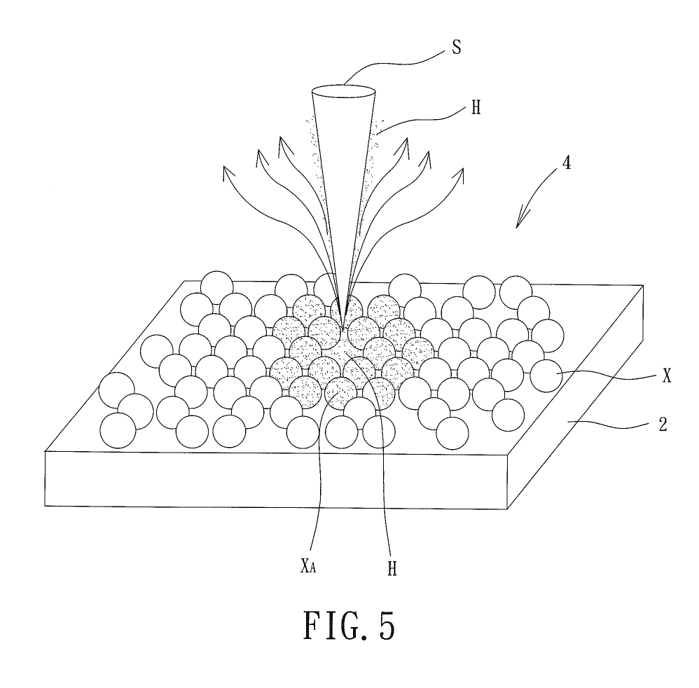

Based on this, during the switching process of the resistance state (such as reset), the filament can be heated as the input energy increases, achieving a high switching speed of the resistance state. However, the heat “H” in the working range “R” will inevitably dissipate as shown in FIG. 5. As a result, when the resistive random access memory is in a lower temperature (such as 77K), the required heating time of the filament is longer. This causes an undesired effect in facilitating the switching process of the resistance state. In light of this disadvantage, the structure of the resistive random access memory can be modified to reduce the negative effect. For example, in order to prevent the heat dissipation though the use of the heat preserving element 3, the first electrode layer 2 and the second electrode layer 5, the first electrode layer 2 can be moved into the through-hole 31 of the heat preserving element 3 to speed up the switching process of the resistance state. However, it is not used to limit the disclosure, as elaborated later.

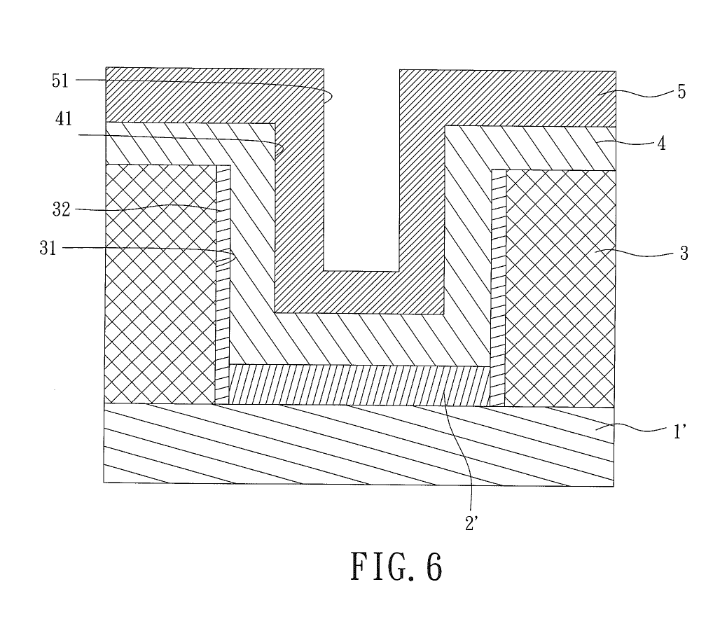

FIG. 6 is a cross sectional view of a resistive random access memory according to a second embodiment of the disclosure. The resistive random access memory of the second embodiment of the disclosure may include a thermally conductive layer 1′, a first electrode layer 2′, a heat preserving element 3, a resistance changing layer 4 and a second electrode layer 5. The heat preserving element 3, the resistance changing layer 4 and the second electrode layer 5 in the second embodiment are substantially the same as those in the first embodiment. In the embodiment, the heat preserving element 3 is arranged on the thermally conductive layer 1′, surrounds the first electrode layer 2′, and forms the through-hole 31. The resistance changing layer 4 extends from the first electrode layer 2′, which is located in the through-hole 31 of the heat preserving element 3, to a surface of the heat preserving element 3. The second electrode layer 5 is arranged on the resistance changing layer 4. The thermally conductive layer 1′ is made of a substantially similar material as the thermally conductive layer 1 in the first embodiment, and the first electrode layer 2′ is made of a substantially similar material as the first electrode layer 2 in the first embodiment. In such an arrangement, the first electrode layer 2′ is moved into the through-hole 31 of the heat preserving element 3. Therefore, the interface between the first electrode layer 2′ and the resistance changing layer 4 is in the through-hole 31, so that the switching process of the resistance state can be speeded up via the electrothermal effect.

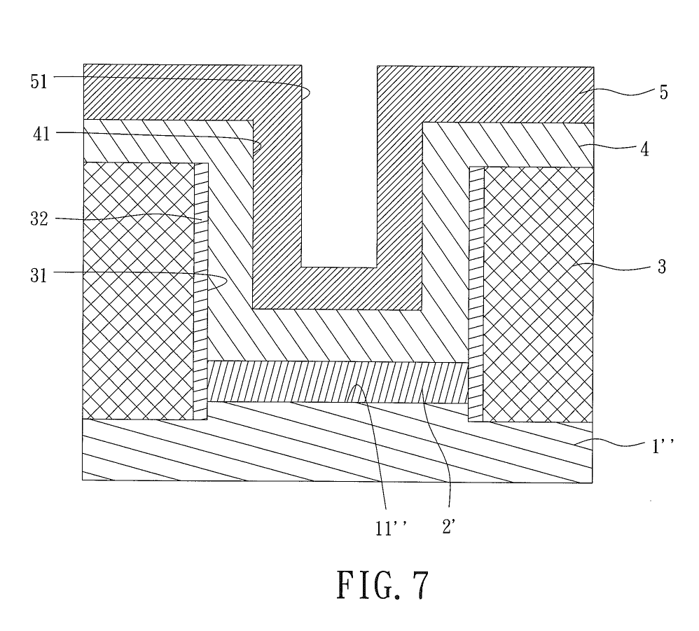

FIG. 7 is a cross sectional view of a resistive random access memory according to a third embodiment of the disclosure. The resistive random access memory of the third embodiment of the disclosure may include a thermally conductive layer 1″, a first electrode layer 2′, a heat preserving element 3, a resistance changing layer 4 and a second electrode layer 5. The first electrode layer 2′, the heat preserving element 3, the resistance changing layer 4 and the second electrode layer 5 in the embodiment are substantially the same as those in the first embodiment. In the embodiment, the thermally conductive layer 1″ includes a protrusion 11″, and the first electrode layer 2′ is arranged on the protrusion 11″. The protrusion 11″ and the first electrode layer 2′ are located in the through-hole 31 of the heat preserving element 3. The protrusion 11″ includes a periphery that is securely coupled with (such as in a threaded manner) an inner periphery of the thermally insulating layer 32 forming the through-hole 31, so as to further reduce the heat dissipation of the through-hole 31. In this arrangement, the interface between the first electrode layer 2′ and the resistance changing layer 4 will be located further inwards of the through-hole 31, thereby providing an improved heat insulating effect and speeding up the switching process of the resistance state.

In this arrangement, the heat can be spread over the resistance changing layer 4 in a higher speed by the thermally conductive layer 1, 1′, 1″ and the first electrode layer 2, 2′ while dissipation of the electrothermal energy is minimized by the heat preserving element 3. As such, the amount of the oxygen ions that are thermally activated can increase, facilitating the formation of the filament and speeding up the switching process of the resistance state. Since the resistive random access memories according to the first, second and third embodiments are able to change the resistance state in a higher speed, the time of data access is shortened, thus speeding up the data access. As such, the resistive random access memories according to the first, second and third embodiments can be used in an equipment which requires a high data access speed (such as a real-time operating system). The resistive random access memories according to the first, second and third embodiments can also shorten the calculation time when a large amount of data is processed, thus facilitating the industrial development.

Although the disclosure has been described in detail with reference to its presently preferable embodiments, it will be understood by one of ordinary skill in the art that various modifications can be made without departing from the spirit and the scope of the disclosure, as set forth in the appended claims.

What is claimed is:

1. A resistive random access memory comprising:
a thermally conductive layer;
a first electrode layer arranged on the thermally conductive layer;
a heat preserving element arranged on the first electrode layer and forming a through-hole, wherein a part of a surface of the first electrode layer is exposed to the through-hole;
a resistance changing layer extending from the part of the surface of the first electrode layer to a surface of the heat preserving element that is located outside the through-hole; and
a second electrode layer arranged on the resistance changing layer.

2. A resistive random access memory comprising:
a thermally conductive layer;
a first electrode layer arranged on the thermally conductive layer;
a heat preserving element arranged on the thermally conductive layer, surrounding the first electrode layer, and forming a through-hole, wherein the first electrode layer is located in the through-hole;
a resistance changing layer extending from the first electrode layer to a surface of the heat preserving element that is located outside the through-hole; and
a second electrode layer arranged on the resistance changing layer.

3. The resistive random access memory as claimed in claim 2, wherein the thermally conductive layer comprises a protrusion, wherein the first electrode layer is arranged on the protrusion, and wherein the protrusion and the first electrode layer are located in the through-hole of the heat preserving element.

4. The resistive random access memory as claimed in claim 3, wherein the protrusion comprises a periphery that is securely coupled with an inner periphery of the thermally insulating layer forming the through-hole.

5. The resistive random access memory as claimed in claim 1, wherein the thermally conductive layer is made of gold, silver, copper, iron, aluminum, or any combination thereof.

6. The resistive random access memory as claimed in claim 2, wherein the thermally conductive layer is made of gold, silver, copper, iron, aluminum, or any combination thereof.

7. The resistive random access memory as claimed in claim 1, wherein the heat preserving element is a composition including silicon dioxide or hafnium dioxide.

8. The resistive random access memory as claimed in claim 2, wherein the heat preserving element is a composition including silicon dioxide or hafnium dioxide.

9. The resistive random access memory as claimed in claim 7, wherein the heat preserving element comprises a thermally insulating material with a thermal conductivity of smaller than 1.26 W/m·° C.

10. The resistive random access memory as claimed in claim 8, wherein the heat preserving element comprises a thermally insulating material with a thermal conductivity of smaller than 1.26 W/m·° C.

11. The resistive random access memory as claimed in claim 7, wherein the heat preserving element comprises a thermally insulating layer surrounding a part of the resistance changing layer.

12. The resistive random access memory as claimed in claim 8, wherein the heat preserving element comprises a thermally insulating layer surrounding the first electrode layer and a part of the resistance changing layer.

13. The resistive random access memory as claimed in claim 11, wherein the thermally insulating layer is made of reinforced carbon-carbon composite, high temperature reusable surface insulation tiles, fibrous refractory composite insulation tiles, flexible insulation blankets, or toughened unipiece fibrous insulation.

14. The resistive random access memory as claimed in claim 12, wherein the thermally insulating layer is made of reinforced carbon-carbon composite, high temperature reusable surface insulation tiles, fibrous refractory composite insulation tiles, flexible insulation blankets, or toughened unipiece fibrous insulation.

15. The resistive random access memory as claimed in claim 1, wherein the resistance changing layer forms a recess extending into the through-hole of the heat preserving element.

16. The resistive random access memory as claimed in claim 2, wherein the resistance changing layer forms a recess extending into the through-hole of the heat preserving element.

17. The resistive random access memory as claimed in claim 15, wherein the second electrode layer extends from the recess to a surface of the resistance changing layer, wherein the surface of the resistance changing layer is located outside the recess, wherein the second electrode layer forms a notch located in the recess of the resistance changing layer.

18. The resistive random access memory as claimed in claim 16, wherein the second electrode layer extends from the recess to a surface of the resistance changing layer, wherein the surface of the resistance changing layer is located outside the recess, wherein the second electrode layer forms a notch located in the recess of the resistance changing layer.

19. The resistive random access memory as claimed in claim 1, wherein the resistance changing layer is a composition of silicon dioxide and hafnium dioxide.

20. The resistive random access memory as claimed in claim 2, wherein the resistance changing layer is a composition of silicon dioxide and hafnium dioxide.
